(19) United States
(12) Patent Application Publication
(10) Pub. No.: US 2015/0134280 A1
(43) Pub. Date: May 14, 2015

(54) SCALABLE AND WEB-BASED DR PLATFORM FOR COMMUNICATION OF A DR SIGNAL USING A NETWORK SERVER

(71) Applicants: Amit Narayan, Cupertino, CA (US); Rajeev Kumar Singh, Redwood City, CA (US); Abishek Bahl, San Francisco, CA (US); Vijay Srikrishna Bhat, San Francisco, CA (US)

(72) Inventors: Amit Narayan, Cupertino, CA (US); Rajeev Kumar Singh, Redwood City, CA (US); Abishek Bahl, San Francisco, CA (US); Vijay Srikrishna Bhat, San Francisco, CA (US)

(73) Assignee: AUTOGRID INC., Redwood Shores, CA (US)

(21) Appl. No.: 14/345,255

(22) PCT Filed: Sep. 14, 2012
(86) PCT No.: PCT/US12/00400

§ 371 Date: Sep. 26, 2014

Related U.S. Application Data
(60) Provisional application No. 61/535,365, filed on Sep. 16, 2011.
(60) Provisional application No. 61/535,369, filed on Sep. 16, 2011.
(60) Provisional application No. 61/535,371, filed on Sep. 16, 2011.

(51) Int. Cl. G01R 21/00; H04L 29/08

(52) U.S. Cl. CPC G01R 21/00; H04L 67/141
USPC 702/62; 709/227

(57) ABSTRACT

A scalable and web-based demand response platform for optimization and management of Demand response resources are provided. The optimization and management are achieved by using a server, a program design module, a customer portal module, a forecasting optimization module, an event management module, an application programming interface, an analytics module for performing analysis for performing analysis of the data feeds. The said platform is offered to the users on software-as-a-service model.

### CROSS-REFERENCE TO RELATED APPLICATION(S)

This application claims the benefit of priority to U.S. Provisional Patent Application No. 61/535,369, filed Sep. 16, 2011, entitled “Software-as-a-Service (SaaS) for Optimization and Management of Demand Response and Distributed Energy Resources”, and claims the benefit of priority to U.S. Provisional Patent Application No. 61/535,365, filed Sep. 16, 2011, entitled “System and Method for Optimization of Demand Response and Distributed Energy Resources and Management Thereof”, and claims the benefit of priority to U.S. Provisional Patent Application No. 61/535,371, filed Sep. 16, 2011, entitled “Multi-Channel Communication of Demand Response Information between Server and Client”, the contents of each of which are hereby incorporated by reference in their entireties.

### FIELD OF THE INVENTION

The present invention relates generally to Demand Response (DR) management, and more particularly to a communication channels for real-time demand response signaling between server and clients. Furthermore, the system can be used as Software-as-a-Service (SaaS) model.

### BACKGROUND

Demand response (DR) is a mechanism to manage customer consumption of electricity in response to supply conditions, for example, customers can reduce their electricity consumption at critical times or in response to market prices. Demand Response is generally used to encourage consumers to reduce demand thereby reducing the peak demand for electricity. Demand response gives the consumers the ability to voluntarily trim or reduce their electricity usage at specific times of the day during high electricity prices, or during emergencies.

Automation of demand response (DR) programs is widely accepted as an effective industry solution for shifting and shedding electric loads. Unfortunately, many of the industry solutions available today are not standardized, creating problems for utilities, aggregators and regulators. The OpenADR Alliance was formed to accelerate the development, adoption and compliance of OpenADR standards throughout the energy industry.

Demand response (DR) is a set of actions taken to reduce load when electric grid contingencies threaten supply-demand balance or market conditions occur that raise electricity costs. Automated demand response consists of fully automated signaling from a utility, ISO/RTO or other appropriate entity to provide automated connectivity to customer end-use control systems and strategies. OpenADR provides a foundation for interoperable information exchange to facilitate automated demand response.

The OpenADR Alliance includes industry stakeholders that are interested in fostering the deployment of low-cost and reliable demand response communication protocol by facilitating, and accelerating the development, and adoption of OpenADR standards and compliance with standards. These standards include de fa standards based on specifications published by LBNL in April 2009, as well as smart grid-related standards emerging from OASIS, UCA and NAESB.

In the existing technologies demand response platform requires extensive installation at the individual user site. The installation and upgrade of hardware and software at the individual user site is very costly and difficult.

Unlike traditional software where upgrades would happen once a year or once in 6 months (with the vendor coming to your office with a CD), the SaaS customers have immediate access to the new features and functionality by paying a subscription amount. The software-as-a-service vendor continuously pushes new updates and fixes to the application and makes it immediately accessible by the customer. This reduces the time and expense associated with software upgrade and maintenance.

In the traditional model a customer buys a license to the software and acquires ownership for its maintenance and installation, whereas in case of software-as-a-service (SaaS) the ownership for its maintenance and installation remains with the vendor. It is a new model for delivering software. Software-as-a-service refers to software that is accessed via a web browser through payment on monthly or yearly subscription basis.

Today's demand response system requires extensive direct investment in the IT infrastructure and personnel to design and implement a new program. At pilot scales these investments are hard to justify, and since most pilots don't reach the scale necessary to pay back the direct expense, utilities are reluctant to make these investments. Even when using the conventional IT model, the higher cost of implementing the programs needs to be passed on to the consumers making them less attractive. By providing the software-as-a-service (SaaS) model, DROMS-RT eliminates this big barrier towards offering new programs. The system is able to use new programs in an easy and cost-effective manner. It introduces many more programs to serve different areas of the customers, and to achieve higher acceptance and customer satisfaction.

### BRIEF SUMMARY OF THE INVENTION

Accordingly in an aspect of the present invention a scalable, web-based demand response platform for optimization and management of demand response resources is provided. The system is comprised of a server having a storage media, a processor and a computer readable media; a program design module to add, view and edit demand response programs and constraints associated with a demand response event; a customer portal module for managing information of utility operators, participants and system operators; a forecasting optimization module to calculate baseline quantities as well as load sheds and customer payments; an event management module for manual and automated event creation and schedule notifications; an application programming interface communicatively coupled to the server for bidirectional communication of data-feeds from the utility's backend data system and the customer end-point, for measurement settlement and verifications; an analytics, module for performing analysis for performing analysis of the data feeds, wherein the said platform is made available to the users on software-as-a-service model.

In another aspect of the present invention a network server implemented system for facilitating communication of a demand response signal is provided. A demand response server hosted in the cloud network; a network of utility operators and independent system operators connected to a plurality of electric customers at different sites through the demand response server; an application programming interface configured with the demand response server, the said application programming interface enables the demand response server to communicate with the API of the utility operators, the independent system operators, the electric customers and the load aggregators, wherein the said communication is done through simultaneous multi-channel communication protocols and physical medium.

### BRIEF DESCRIPTION OF THE DRAWINGS

The preferred embodiment of the invention will hereinafter be described in conjunction with the appended drawings provided to illustrate and not to limit the scope of the invention, wherein like designation denote like element and in which:

FIG. 1 is a block diagram illustrating the operation of a Demand Response Optimization and Management System for Real-Time for generating user profile specific algorithm and to support large scale integration of distributed renewable generation into the grid in accordance with an embodiment of the present invention.

FIG. 2 is a schematic. representation of dynamic demand response (DR) resource model inputs and portfolio of dynamic demand response (DR) resources in accordance with an embodiment of the present invention.

FIG. 3 is a schematic diagram illustrating the Multi-Channel Communication of Demand Response Information between Server and Client.

FIG. 4 is a schematic diagram illustrating an OpenADR, a communications data model designed to facilitate sending and receiving of demand response signals from a utility or independent system operator to electric customers in accordance with an embodiment of the present invention.

### DETAILED DESCRIPTION OF THE EMBODIMENTS

The present invention demonstrates that off-the-shelf communication technology based on internet protocols can be adapted, and used for real-time DR application. Furthermore, it can provide an adequate level of security, and reliability for mission-critical grid operations at a relatively lower cost. Software-as-a-Service (SaaS) business model for optimization and management of demand response and distributed energy resources is provided.

In an embodiment of the present invention the main objective is to build a scalable, web-based software-as-a-service platform that provides all program design, program implementation, program execution, event management, forecasting, optimal dispatch and post-event analytics functionality. The optimal dispatch decisions can be made and reliably communicated to millions of end-points in the time-scales necessary for providing ancillary services ensuring scalability, reliability, fault-tolerance and throughput requirements.

Software-as-a-Service (SaaS) is a software application delivery model by which a utility can host and operate a web based software application over the Internet for use by its customers. The software and its associated data are hosted centrally and are accessed by users through the internet.

The implementation of Software-as-a-Service (SaaS) is faster and more cost effective than existing models of software distribution. There are no hardware and implementation or acquisition costs involved to run the application from the customer's side. It's the responsibility of the Software-as-a-Service vendor to manage and run the application with utmost security, performance and reliability.

Software-as-a-Service (SaaS) model provides a platform that can reduce the cost of deployment and facility, and allows all small, commercial and residential customers to participate in demand response.

Furthermore the Software-as-a-Service (SaaS) is on-demand software provided as a service to end users. It is a delivery model in which software and its associated data are hosted centrally and are accessed by users through the internet. The Software-as-a-Service (SaaS) platform provides facilities to make projects scalable, and reliable. Furthermore, SaaS provides a platform for all program design, resource modeling, forecasting, optimal dispatch, and measurement functionality.

The Software-as-a-Service (SaaS) platform is designed for implementation and management of demand response programs. The system architecture for developing SaaS platform comprises a server, a program design module, a customer portal module, a forecasting optimization module , an event management module ,an application programming interface communicatively coupled to the server for bidirectional communication of data-feeds from the utility's backend data system and the customer end-point, for measurement settlement and verifications, an analytics module for performing analysis for performing analysis of the data feeds.

The server of the system architecture uses OpenADR standards for signaling and is hosted in the cloud network through a web interface and is distributed across a multiple geographical location. The software as a service platform has customer portal modules which are operated through a web interface and the information managed by the customer portal module includes adding participants, and subscribing or unsubscribing participants from a program.

In another embodiment of the present invention, a multichannel communication between server and client in DROMS-RT (Demand response Optimization and Management System for Real Time) is required to provide or facilitate the exchange of data between different client nodes that are connected to the centralized server system via internet cloud. A server is a computer, or series of computers, that link other computers or electronic devices together. It provides essential services across a network, either to private users inside a large organization or to public users via the internet. A client is an application or system that accesses a service made available by a server.

Activity logs are transmitted by the client devices that are then received and processed on the other end to perform robust, optimized, and error free real time events. Multichannel communication between server and client is required to provide or facilitate the exchange of data in between different client nodes that are connected to the centralized server system via internet cloud.

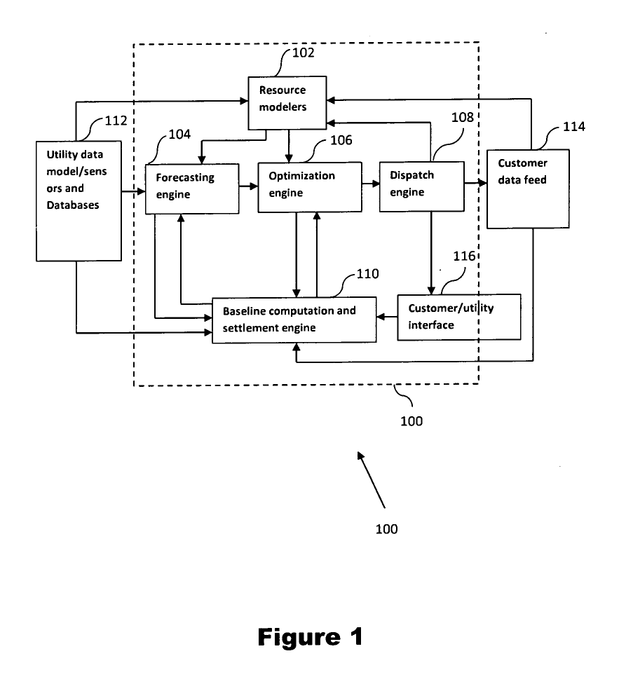

FIG. 1 is a schematic diagram illustrating the working of the system in accordance with an embodiment of the present invention. Referring to FIG. 1 an architecture for optimization and management of demand response system in real time that can be offered under Software-as-a-Service (SaaS) model is provided. The system 100 comprises: a resource modeler 102, a forecasting engine 104, an optimization engine 106, a dispatch engine 108, and a baseline computation and settlement engine 110. DROMS-RT is coupled to the utility's backend data system 112 on the one side and customer end-points 114 on the other side.

The DR Resource Modeler (DRM) 102 within the system 100 keeps track of all the available DR resources, their types, their locations and other relevant characteristics such as response times, ramp-times etc. The Forecasting Engine (FE) 104 gets the list of available resources from the resource modelers; its focus is to perform short-term forecasts of aggregate load and available load-sheds for individual loads connected to the system 100. In practice, some of the feeds might not be available all the time or in real-time; in these cases the forecasting engine is able to run in an “off-line” manner or with partial data feeds. The Optimization Engine (OE) 106 takes the available resources and all the constraints from the Demand Response Resource Modeler and the forecasts of individual loads and load-sheds and error distributions from the forecasting engine to determine the optimal dispatch of demand response under a given cost function. Baseline computation and Settlement Engine 110 uses signal processing techniques to identify even small systematic load sheds in the background of very large base signals. The system is coupled to customer data feed 114 on one side for receiving live data-feeds from customer end-devices. The system is coupled to utility data feed 112 on another side and the data from the utility data feed 112 is provided to calibrate the forecasting and optimization models to execute demand response events. The system 100 has a dispatch engine 108 that helps in taking decision and uses these resource specific stochastic models to dispatch demand response signals across a portfolio of customers to generate (International Standard Organization)ISO bids from demand response or to optimally dispatch demand response signals to the customer based on the cleared bids and other constraints of the grid. The system uses customer/utility interface 116 connected to baseline engine that provides an interface between the system and customer or the utility. The goal of the system 100 is to provide near real-time DR event and price signals to the customer end-points to optimally manage the available demand response resources.

The demand response resource modeler 102 monitors the constraints associated with the demand response event which includes event duration, notification window, black-out time, valid times, number of times a customer can be asked to participate in the event. The demand response resource modeler 102 also monitors the constraints associated with each resource such as the notification time requirements, number of events in a particular period of time and number of consecutive events. It can also monitor user preferences to determine a “loading order” as to which resources are more desirable for participation in demand response events from a customer's perspective, and the contract terms the price at which a resource is willing to participate in an event. The demand response resource modeler also gets a data feed from the client to determine whether the client is “online” (i.e. available as a resource) or has opted-out of the event.

The Forecast Engine 104 accounts for a number of explicit and implicit parameters and applies machine learning (ML) techniques to derive short-term load and shed forecasts as well as error distributions associated with these forecasts.

The overall robustness of optimization is improved by the estimation of error distribution, that further helps separate small load sheds during the events. Forecasting Engine gets continuous feedback from the client devices through the baseline engine and increases its forecasting ability as more data becomes available to the system. Forecasting Engine can also update the demand response resource modeler about the load preferences by implicitly learning what type of decisions the client devices are making to the DR event offers.

The optimization engine (OE) (106) can incorporate a variety of cost functions such as cost, reliability, loading order preference, GHG or their weighted sum and can make optimal dispatch decisions over a given time-horizon that could cover day-ahead and near real-time horizons simultaneously. The system is able to automatically select the mix of DR resources best suited to meet the needs of the grid such as peak load management, real-time balancing, regulation and other ancillary services.

A mathematical formulation of the optimization problem is used to know how approximate dynamic programming (ADP) algorithm can be used to solve the problem. The optimization also takes into account the errors in the distribution itself and can execute a robust ADP algorithm that avoids control policies that result in very abruptly changing, erratic price, and demand trajectories. The Optimization engine 106 can also be used to generate bids for wholesale markets given the information from demand response resource modeler 102, and the wholesale market price forecasts that can be supplied externally.

The baseline computation and settlement engine (BE) (110) verifies whether a set of customers have all met their contractual obligation in terms of load-sheds. Baseline computation and settlement engine uses signal processing techniques to identify even small systematic load sheds in the background of very large base signals.

The system 100 uses advanced machine learning and robust optimization techniques for real-time and “personalized” DR-offer dispatch. It keeps a unified view of available demand side resources under all available demand response programs and history of participation in different demand response events at individual customer locations. The demand response resource models are dynamic, as it varies based on current conditions and various advanced notice requirements.

Historical time-series data from past participation is used to build a self-calibrated model for each customer that will be able to forecast, shed capacity, ramp time and rebound effects for that customer, given the time-of-day, weather and price signal. Use of machine learning algorithms allows using many variables such as occupant feedback to improve the forecast accuracy.

These profiles are “stochastic” in nature and the forecast also quantifies individual resource variability. The system 100 incorporates a decision engine that uses these resource specific stochastic models to dispatch demand response signals across a portfolio of customer to generate ISO bids from demand response or to optimally dispatch demand response signals to the customer based on the cleared bids and other constraints of the grid. A variety of cost functions including cost, reliability, loading order preference; GHG etc. have been incorporated in the decision engine.

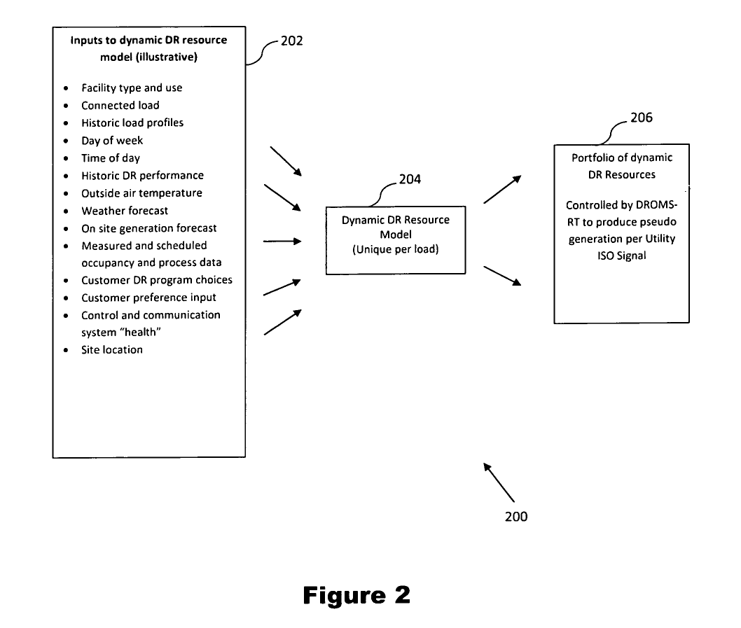

FIG. 2 is a schematic diagram showing Dynamic DR Resource Model. inputs and Portfolio of Dynamic DR Resources in accordance with an embodiment of the present invention. Referring to FIG. 2, a Dynamic DR Resource model (204) unique for every load is provided. The model takes facility type and use, connected load, historic day profiles, day of week, time of day, historic demand response performance, outside air temperature, weather forecast, on site generation forecast, measured and scheduled occupancy and process data, customer demand response program choices, control and communication system health and site location information as inputs (202) in order to create a portfolio of DR Resources (206) that is further used by the system 100 to produce pseudo generation per utility ISO Signal.

The system 100 can manage a portfolio of demand response resources of various performance characteristics over a given time-horizon that would span both day-ahead and near real-time situations. The system 100 can automatically select the mix of demand response resources best suited to meet the needs of the grid (such as reduce congestion in targeted regions, provide contingency peak reduction, regulation and other ancillary services).

Robust optimization techniques that can effectively deal with uncertainty in model parameters have been used to optimize demand offers generated for individual customers. DR is viewed as an online learning and optimization problem, where the decision maker learns the demand distribution and makes demand-shaping decisions. Reacting to the current maximum likelihood, estimate of the demand can lead to control policies that result in very abruptly changing, erratic price and demand trajectories. The robust optimization approach stabilizes this volatility and delays changes until the uncertainty in distribution has been sufficiently resolved.

The system 100 is based on the nationally recognized, NIST certified communications data model known as OpenADR (Open Automated Demand Response) Automation of Demand Response (DR) programs is widely accepted as an effective industry solution for shifting and shedding electric loads. Automated demand response consists of fully automated signaling from a utility, ISO/RTO or other appropriate entity to provide automated connectivity to customer end-use control systems and strategies. OpenADR provides a foundation for interoperable information exchange to facilitate automated demand response. OpenADR is an Open Automated Demand Response, which is applied to a set of communication specifications. OpenADR allows the system 100 to directly interface with an increasing number of building energy management systems. The energy management systems already have OpenADR for day-ahead markets, and accounts for over 100 MW capacity, and adopted by over 60 utility and smart-grid vendors.

The OpenADR specification is extended to deal with the real-time requirements of providing ancillary services. Through the adoption of fully-automated OpenADR communications protocols, DROMS-RT minimizes or eliminates the need for “human in the loop” controls.

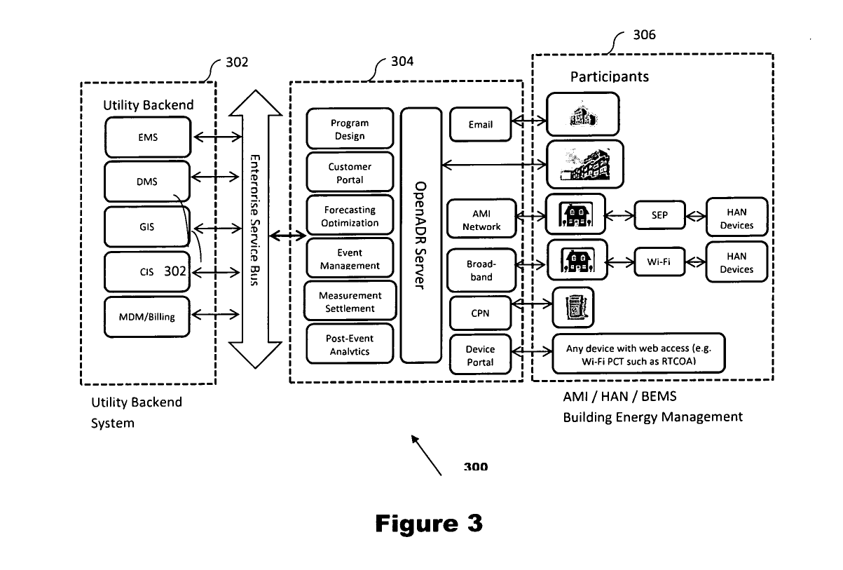

FIG. 3 is a schematic diagram illustrating a two way communication using OpenADR server in accordance with an embodiment of the present invention. Referring to FIG. 3, there is a two way communication between OpenADR server (304) and participants (306) using email, AMI network, Broadband or CPN. Any device with web access like Wi-Fi PCT such as RTCOA can also communicate with the server through the device portal in the server. The server communicates with the Utility Backend Systems (302) like EMS, DMS, GIS, CIS and MDM/Billing in order to receive signals indicating the type and duration of ancillary services needed.

Multichannel communication of demand response includes public internet connection, Wi-Fi, RDS (Radio Data System), e-mail, text, and phone for the purpose of providing many web based services such as program design, resource modeling, forecasting, optimal dispatch, and measurement functionality. The schedule notification of event will support multi-channel communications like Wi-Fi, RDS, e-mail, and phone.

Secure, low-cost communication channels and protocols that enable the OpenADR specification to be used for real-time DR signaling have been tested.

OpenADR is a communication data model designed to facilitate sending and receiving of DR signals from a utility or independent system operator to end-point user. The intention of the data model is to interact with building and industrial control systems that are pre-programmed to take action based on a DR signal, enabling a demand response event to be fully automated, with no manual intervention. Open specification is intended to allow anyone to implement the signaling systems, the automation server or the automation clients. This system is be deployed worldwide and under the guidance of the National Institute of Standards and Technology (NIST).

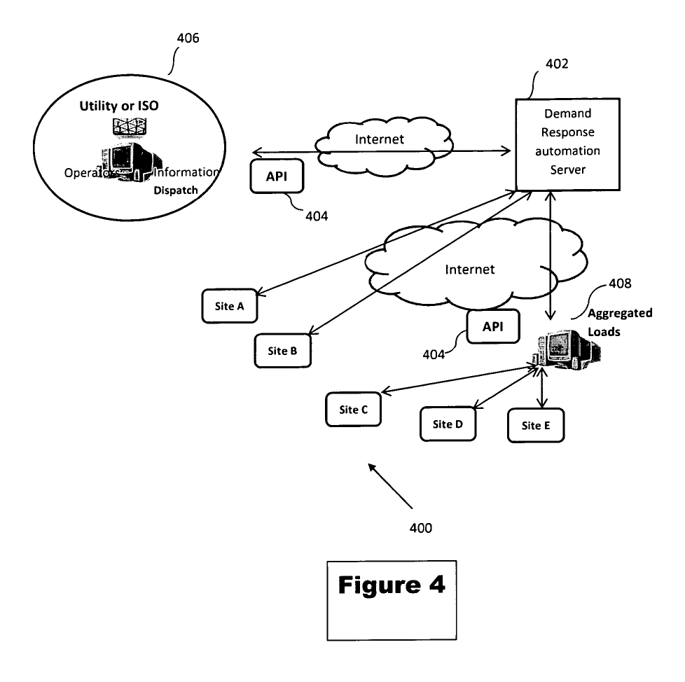

FIG. 4 is a schematic diagram illustrating an OpenADR, a communications data model designed to facilitate sending and receiving of DR signals from a utility or independent system operator to electric customers in accordance with an embodiment of the present invention. Referring to FIG. 4, a demand response automation server (402), a standardized application programming interface (API) (404), load aggregators (408),and plurality of sites like site A, site B, site C, site D and site E is shown. The demand response automation server (402) is configured to a standardized application programming interface (API) (404) to communicate with load aggregators (408) at plurality of sites like site C, site D, site E, utility or independent system operator (ISO) or customer sites like site A and Site B through a network cloud using multiple communication protocols and physical mediums in order to send and receive Demand Response signals from a utility or independent system operator (ISO) to the customers.

The OpenADR server of the system 100 is hosted in the cloud, is distributed across multiple geographic regions and is accessible through internet. The demand response server uses openADR standards for signaling. The utility operators and independent system operators are connected to the customers through the demand response server using web API. The signal communication between customers and the demand response server is bidirectional and demand response servers transfers the demand response signals to the customers directly or through load aggregators

The system 100 uses a load-balancer to spread computational load across a cluster of servers with capability to grow and shrink the cluster in response to load.

The system 100 uses a 24×7 monitoring and alerting systems e.g. Nagios, Ganglia in addition to monitoring and alerting capabilities offered by the cloud infrastructure provider.

SQL is a Structured Query Language for accessing and manipulating databases. It is a programming language designed for managing data in relational database management systems (RDBMS).The system 100 has full SQL database replication to a “hot standby” in multiple different zones for failover.

DROMS-RT architecture has inherent fault-tolerance capabilities (via data-block replication) of NoSQL databases/HadoopFilesystem (HDFS) which are designed for and expect server/component failures during normal operation without affecting the overall system behavior.

Automated deployment of DROMS-RT using Chef Server recipes that enables rapid deployment to another geographical location or even to another cloud infrastructure provider in the worst case.

In addition to using open standards such as OpenADR and EnergyInterOp, the system 100 server can communicate to any proprietary client API using “proxies”. These proxies are loosely coupled software agents that run within DROMS-RT server to convert the communication between a standards compliant server to devices specific APIs

The system 100 unique architecture allows creation of any number of proxies and run simultaneously as separate processes. DROMS-RT is capable of handling millions of such proxies simultaneously in a reliable and fault-tolerant manner.

The system 100 server receives signals from the ISO/RTO system indicating the type and duration of ancillary services needed. This system 100 server then optimally dispatches the demand-side resources to act as “pseudo-generators” to meet the ramp-rate and shed-duration requirements of the grid operators.

All previous implementations of OpenADR based servers are not capable of simultaneous multi-channel communication such as over e-mail, text, RDS, broadband Internet and cellular link using a multitude of communication protocols such as OpenADR, Smart Energy Profile 1.x/2.x and EnergyInterOp. This severely limits the applicability of DR and increases the management cost of DR programs as the customers and utility service providers have to constantly worry about interoperability and need separate IT infrastructure to manage end-devices using different protocols.

The system 100 is capable of providing two-way communication between the server and end-devices using multiple channels. The end-point devices can communicate their intention to participate or ‘opt-out’ of any particular DR event using an ‘acknowledgement’ mechanism that is also multi-channel and can use email, Internet or advanced metering infrastructure (AMI).

What is claimed is:

1. A software-as-a-service platform for optimization and management of Demand response resources comprising:
a server having a storage media, processor and a computer readable media, communicatively coupled to utility operator's system and customer end-point;
a first module in the server for design of a Demand response event, the said first module allows the user to add, view and edit a demand response event;
an application programming interface communicatively coupled to the server that allows bidirectional communication of data-feeds from the utility operator's system and the customer end-point, for measurement settlement and verifications;
a second module for analysis of the data feeds provided by the application programming interface, the said second module calculates baseline quantities of electricity usage, load sheds and payments associated with the demand response event designed in the first module.

2. The platform of claim 1 wherein the server uses OpenADR standards for signaling.

3. The platform of claim 1 wherein the server is hosted in the network through a web interface and is distributed across a multiple geographical location.

4. The platform of claim 1 wherein the demand response event includes event duration, notification window, black-out time, valid times, number of times a customer can be asked to participate in the event.

5. The platform of claim 1 wherein the second module uses a baseline computation method for calculating baseline and load-sheds.

6. The platform of claim 1 wherein the data-feeds from the utility operator's includes EMS, DMS, GIS, CIS, MDM and Billing systems.

7. A network server implemented system for facilitating communication of a Demand response signal comprising:
a demand response server hosted in the cloud network;
a network of utility operators in the network distributing the electricity to a group of customers, the said utility operators are using utility backend data system for electricity distribution;
a first application programming interface that enables the demand response server to communicate with the network of utility operators;
a second application programming interface that enables the demand response server to communicate with the customers,
wherein the said communication is done through simultaneous multi-channel communication protocols.

8. The system of claim 7 wherein the demand response server hosted in the cloud network is distributed across multiple geographical locations and is accessible through internet.

9. The system of claim 7 wherein the demand response server uses openADR standards for signaling.

10. The system of claim 7 wherein the utility operators and independent system operators are connected to the customers through the demand response server using web API.

11. The system of claim 7 wherein the signal communication between customers and the demand response server is bidirectional.

12. The system of claim 7 wherein the demand response servers transfers the Demand response signals to the customers directly or through load aggregators.

13. The system of claim 7 wherein the communication between demand response server communicates with customer API through proxies that convert communication between a standards compliant server to devices specific APIs.

14. The system of claim 7 wherein the system is compatible with simultaneous operation of multichannel communications and protocols.

15. The system of claim 7 wherein the multichannel communication includes e-mail, text, RDS, broadband, internet, and cellular link.

16. The system of claim 7 wherein the communication protocols include OpenADR, smart energy profile 1.x/2.x, and Energy InterOp.
